(19) United States
(12) Patent Application Publication
(10) Pub. No.: US 2022/0305914 A1
(43) Pub. Date: Sep. 29, 2022

(54) DISPLAY DEVICE

(71) Applicant: Robert Bosch GmbH, Stuttgart (DE)

(72) Inventor: Thomas Vogt, Ludwigsburg (DE)

(21) Appl. No.: 17/695,149

(22) Filed: Mar. 15, 2022

(30) Foreign Application Priority Data
Mar. 23, 2021 (DE) 10 2021 202 783.0

(51) Int. Cl. B60K 35/00

(52) U.S. Cl. CPC B60K 35/00; B60K 2370/816; B60K 2370/152

(57) ABSTRACT

A display device for a vehicle, in particular for the placement in an instrument panel region of the vehicle. The display device includes a display element having an electronic display element, a cover element being situated at a surface of the display element, and a frame element, which at least partly, in particular circumferentially, surrounds the cover element. The frame element is connected via a first bonded joint to the cover element, and the frame element is connected via a second bonded joint to the carrier element.

### FIELD

The present invention relates to a display device for a vehicle, for example.

### BACKGROUND INFORMATION

German Patent Application No. DE 10 2011 082 933 A1 describes a display device for a motor vehicle is described in which a display panel is fixed in place on a carrier frame with the aid of a liquid adhesive.

### BACKGROUND INFORMATION

A display device for a vehicle is provided in accordance with the present invention. Advantageous embodiments of the present invention are disclosed herein.

Display devices in vehicles can include electronic displays for displaying driving and/or vehicle information, e.g., for the display of information from a navigation system, an entertainment system, a driver assistance system, and others. For instance, such display devices may be placed in the region of an instrument panel of the vehicle. The present display device is provided especially for the display of information such as in image and/or text form, especially driving and/or vehicle information, e.g., information from a navigation system, an entertainment system, a driver assistance system, etc., or also information pertaining to the current state of the vehicle such as current values for the vehicle velocity, the fuel consumption, the battery charge state and others, for instance.

### SUMMARY

In accordance with an example embodiment of the present invention, a display device in particular is provided for being placed in an instrument panel area of the vehicle, e.g., in the center of an instrument panel. More specifically, the display device may be provided as a central information display, CID.

Individual components of the present display device are specifically developed and connected to one another in a specific way so that a slim, compact and stable display device is produced, which is able to be mounted in a vehicle, in particular in an instrument panel region, in an efficient and compact manner. The display device has a cover element, a display element, a frame element, and a carrier element. In addition, the carrier element is preferably at least partly situated in a housing element.

In accordance with an example embodiment of the present invention, the display element has an electronic display element or a display or display module. For practical purposes, the display element is the actual element of the display device for the display of information. For example, the display element may be developed as a TFT or an LCD display and, for instance, have terminals for a connection to a computing unit, e.g., USB ports, HDMI ports, etc.

The cover element is situated at a surface of the display element. In particular, the cover element is provided as a (protective) cover or as a cover element or cover glass for the display element. The cover element is particularly made of a transparent material such as silicates or an amorphous plastic, e.g., polycarbonate (PC) or polymethyl methacrylate (PMMA). More specifically, the display element is connected to the cover element with the aid of an adhesive layer (optical bonding). In an especially advantageous manner, the cover element projects on the side, i.e., parallel to a main extension plane of the cover element, beyond a surface of the display element. The individual components of the display device in particular are assembled in an assembly direction that runs perpendicular to the main extension plane of the cover element or perpendicular to a surface of the cover element.

In accordance with an example embodiment of the present invention, the carrier element particularly is provided as a supporting element in the structure of the display device. For practical purposes, the carrier element is made of light metal, e.g., aluminum or magnesium and their alloys, or also of a plastic material that may be provided with a glass or carbon fiber fill for reasons of stability.

The carrier element is preferably at least partly situated inside a housing element. In particular, the carrier element may also be completely situated inside the housing element. This housing element is especially provided as a rear and side cover of the display device or as a rear and side housing. For practical purposes, the housing element forms the side surfaces and the bottom of the display device. The surface of the display device is advantageously formed by the cover element. The housing element particularly is produced from a plastic material that may be lacquered, for instance. The plastic used may especially be polypropylene (PP), acrylonitrile butadiene styrene copolymer (ABS), and/or polycarbonate (PC). The housing element is specifically provided to protect the individual elements and also the connections between the individual elements of the display device.

In accordance with an example embodiment of the present invention, the frame element or rim element surrounds or frames the cover element at least partly. In particular, the cover element is completely or peripherally surrounded or framed by the frame element. In an advantageous manner, the frame element is thus provided to protect an edge of the cover element. In addition, the frame element may particularly be provided as a decorative frame or design ring or design frame to embellish the display device. In a frontal view, e.g., in a mounted state in the vehicle, in particular only the cover element and part of the frame element are visible to a user. The remaining part of the display device is hidden, especially in the instrument panel region of the vehicle. The frame element, for instance, may be produced from a plastic material, which can of course be dyed or also varnished or galvanically metalized in a post-production process.

In a particularly advantageous manner, the frame element furthermore connects or keeps the further components of the display device together. To this end, the frame element is connected both to the cover element and the carrier element and for practical purposes also to the housing element, in a specific manner in each case.

The frame element is connected to the cover element via a first bonded joint. Via a second bonded joint, the frame element is connected to the carrier element. The type of the first bonded joint particularly differs from the type of the second bonded joint. The frame element is therefore connected to the cover element and the carrier element with the aid of two different types of bonded joints. These bonded joints in particular make it possible to compensate for connection problems that for instance arise as a result of different expansion characteristics of different materials such as glass, plastic and metal.

If a housing element is provided, a mechanical connection advantageously connects the frame element to the housing element. Such a mechanical connection in particular makes it possible to remove the housing element, if necessary, or to remove the unit made up of the cover, display, frame and carrier element from the housing element, for instance in order to carry out repairs. In the present display device, different connection techniques are thus combined with one another to connect individual elements within a tight space. The use of the connection techniques especially makes it possible to produce a very narrow edge of the display device (what is termed a slim rim design). Moreover, in particular the cost of the display device is able to be kept to a minimum, e.g., material and production costs. Great flexibility in a design or product design of the display device is advantageously achievable, e.g., in order to provide product designers with a large range of shapes and materials.

The display device is particularly able to be produced with a narrow, slim design, especially with regard to a distance from an end of the display element to an end of the frame element or to an edge of the display device. In accordance with an example embodiment of the present invention, this may particularly be achieved in that the frame element and the carrier element share the connection or fastening space, especially in that they are not placed next to but underneath or behind one another. In an especially advantageous manner, the use of the connection techniques allows for a stress-free joining and retaining of the interconnected elements. In particular what is known as ‘black uniformity’ is able to be enhanced, that is, the ability of the display device to display the most uniform, homogeneous black tone.

In an advantageous manner, the frame element is connected to the cover element via an adhesive tape, in particular via a double-sided adhesive tape, as the first bonded joint. This adhesive tape in particular is a tape that has a porous foam material in the core. Applied to both sides of the foam core is a thin adhesive layer, in particular. The porous core especially serves the purpose of compensating for unevenness of the adhesive partners and also for compensating for lateral forces that may be created in a thermal expansion of different materials. The adhesive tape thus has the special characteristic of an excellent adhesion to glass and also plastic and metal. The thickness of the adhesive tape advantageously amounts to between 0.3 mm and 0.5 mm. The thickness of the adhesive tape is particularly a function of the length of the bonding surface, in particular in relation to a circumferential direction of the cover element or in relation to a main extension direction of the adhesive tape. The longer the bonding surface, the thicker the adhesive tape.

The frame element is preferably connected to the carrier element via a liquid adhesive as the second bonded joint. This liquid adhesive especially allows for the compensation of unevenness between the carrier element and the frame element. Such unevenness may be produced by the individual production process of the carrier or frame element. The use of the liquid adhesive advantageously does not require any mechanical postprocessing to reduce such unevenness. Through an appropriately selected elasticity of the liquid adhesive, mechanical tensions that in particular may arise in the unit between the frame element and the carrier element on account of different thermal expansions under thermal influences are able to be compensated.

Most preferably, the frame element is connected to the housing element via a mechanical plug-in connection, in particular via a snap-in connection, as the mechanical connection. To this end, the frame element in particular is provided with plug-in elements which are able to enter into a mechanical connection with the housing element or corresponding elements of the housing element. For instance, these plug-in elements may be situated in a flexible manner so that they are able to snap in and out when connected to the housing element in order to thereby ensure the mechanical connection. These plug-in elements may especially be placed at predefined, regular intervals on the frame element. The number of plug-in elements is able to be predefined in particular as a function of the required force for reliably ensuring the connection between the frame element and the housing element. In addition, such a mechanical plug-in or snap-in connection in particular allows for a slim design of the display device. This type of connection especially makes it possible to keep a circumferential gap between the frame element and the housing element constant and small in the assembly direction. This gap is particularly also required to allow for excess pressure and thus a reliable snap-in or clip-in operation of the plug-in elements or clips during the assembly. Such excess pressure is facilitated especially also by the first bonded joint in the form of the double-sided adhesive tape, especially by the foam core of the adhesive tape.

In accordance with an example embodiment of the present invention, in an advantageous manner, the frame element has a connection section by way of which the frame element is connected to a connection section of the cover element and to a connection section of the carrier element. Both the cover element and the carrier element are advantageously fastened to the same section of the frame element, which allows for a compact connection of these elements in the limited space of the display device. This connection section of the frame element has a ring-shaped or frame-shaped design, in particular. A main extension direction of this connection section advantageously lies perpendicular or at least essentially perpendicular to the assembly direction, and furthermore in particular parallel or at least essentially parallel to the main extension plane or surface of the cover element.

Preferably, a first or upper side or a surface of the connection section of the frame element is at least partly or at least regionally connected to the connection section of the cover element. A second or lower side facing away from the first side or a surface of the connection section of the frame element situated counter to the surface is at least partly or at least regionally connected to the connection section of the carrier element. The cover element and the carrier element or their respective connection sections are thus particularly connected to different, advantageously opposite, surfaces of the connection section of the frame element.

The connection section of the cover element, the connection section of the frame element, and the connection section of the carrier element are preferably situated behind one another when viewed in an assembly direction. As described above, the installation direction in particular lies perpendicular to the main extension plane or a surface of the cover element. The main extension directions or main extension planes of these connection sections of the cover, frame and carrier element are thus parallel or at least essentially parallel to one another, in particular. The frame element and the carrier element especially share the space for the connection or fastening, in particular by not being placed next to but underneath or behind one another when viewed in the assembly direction. The display device may thus have a narrow, slim design.

According to one particularly preferred embodiment of the present invention, in addition to the connection section for the connection to the cover element and the carrier element, the frame element also includes a framing section for framing the cover element.

The framing section preferably adjoins this connection section under a predefined angle at an end of the connection section of the frame element. In particular, the framing section is perpendicular or at least essentially perpendicular to the connection section, and furthermore in particular also parallel or at least essentially parallel to the assembly direction. The connection section and the framing section together in particular form an L-shape or at least essentially an L-shape.

In addition, the frame element preferably has a housing section for the connection to the housing element. This housing section preferably extends under a predefined angle on a side or surface of the connection section of the frame element facing away from the framing section. The housing section is especially perpendicular or at least essentially perpendicular to the connection section and furthermore especially parallel or at least essentially parallel to the assembly direction. In an advantageous manner, the housing section does not adjoin the connection section at an end, but is situated in a center region of the connection section, in particular. The connection section and the housing section jointly form a T-shape or at least essentially a T-shape.

In this way, in particular the above-mentioned gap between the frame element and the housing element, especially between the housing element and an area of the connection section of the frame element facing away from the framing section, is able to be kept constant and small in the assembly direction.

In a particularly advantageous manner, this housing section may be provided with plug-in elements which are able to enter into a mechanical connection with the housing element or corresponding elements of the housing element in order to establish the mechanical plug-in or snap-in connection between the frame element and housing element.

According to one advantageous embodiment of the present invention, in addition to the connection section for the connection to the frame element, the cover element also has a cover section. The cover section advantageously covers the display element. In particular, the cover element in this cover section is connected to the display element, e.g., by a bonded joint (optical bonding). The connection section of the cover element advantageously adjoins the cover section and projects beyond the display element. In particular, the cover section covering the display element transitions in one piece or directly or seamlessly into the connection section for the connection to the frame element.

In addition to the connection section for the connection to the frame element, the carrier element also has a carrier bottom and side walls which adjoin the carrier bottom. In an advantageous manner, the bottom has a rectangular or at least essentially rectangular development so that the carrier element especially has four side walls. In particular, the side walls are perpendicular or at least essentially perpendicular to the bottom.

A body of the display element is at least partly situated within the carrier element. This body especially adjoins the surface of the display element. The carrier element at least partly encloses or frames the display element, especially for its protection. The body of the display element is preferably situated at least partly inside a volume which is restricted by the bottom and the side walls of the carrier element.

The connection section of the carrier element preferably adjoins the side walls, in particular at an upper end of the side walls facing away from the bottom. The connection section of the carrier element preferably extends under a predefined angle to the side walls, in particular perpendicular or at least essentially perpendicular to the side walls. In addition, the connection section of the carrier element in particular runs parallel or at least essentially parallel to the bottom. The connection section of the carrier element together with the individual side walls especially form an L-shape or at least essentially an L-shape in each case. In addition, the individual side walls form an L-shape or at least essentially an L-shape together with the bottom. The carrier element is thus developed especially in the form of a trough or a cuboid without a cover surface, and the corresponding connection section extends in the form of a collar or flange at an upper edge of the side walls under an at least essentially right angle.

In an advantageous manner, the housing element has a housing bottom and double walls adjoining the housing bottom. These double walls in particular have two individual walls which are situated at a predefined distance and are set apart from each other by an intermediate region. In particular, these two individual walls of a double wall are disposed parallel to one another or at least essentially parallel to one another. For practical purposes, the housing bottom has a rectangular or an at least essentially rectangular development so that the housing element in particular has four double walls as side walls. In particular, the double walls are situated perpendicular or at least essentially perpendicular to the housing bottom in each case.

In accordance with an example embodiment of the present invention, In an advantageous manner, the carrier element is situated at least partly inside a volume that is restricted by the housing bottom and the double walls. The carrier bottom of the carrier element is advantageously situated parallel or at least essentially parallel to the housing bottom of the housing element. In particular, the side walls of the carrier element are disposed parallel or at least essentially parallel to the double walls or individual walls the housing element.

An intermediate region between the respective individual walls of the double walls is advantageously provided to accommodate the housing section of the frame element. The double walls are thus provided in particular as a mechanical counter element for establishing the mechanical plug-in or snap-in connection between the frame element and the housing element.

At least one snap-in element is preferably provided in each case in the intermediate region of the double walls of the housing element, which cooperates with the housing section of the frame element to form a mechanical connection between the frame element and the housing element. In particular, at least one such snap-in element may be provided on one of the individual walls of a corresponding double wall in each case. These snap-in elements may in particular be provided as a mating piece to the plug-in elements of the housing section of the frame element in order to establish the plug-in or snap-in connection. Thus, plug-in elements or snap-in tabs are provided at a lower side of the frame element, which form a connection with the housing element during the assembly. For example, these plug-in elements or snap-in tabs may be mounted in a flexible manner on the frame element so that they are able to snap in or disengage during the snap-in or clip-in process in order to thereby ensure the plug-in or snap-in connection. For example, a predefined gap or a predefined distance is able to be provided between two plug-in elements in each case. The number of plug-in elements can be predefined, for instance as a function of a force that is required to reliably ensure the connection between the frame element and the housing element.

Preferably, at least one spring element is provided in the intermediate region of the double walls of the housing element, which exerts pressure or a mechanical tension or a compressive force on the housing section of the frame element. Such a spring element particularly makes it possible to ensure that the mechanical connection between the housing element and frame element will not come undone. In addition, such a spring element can keep the unit made up of the housing element and frame element under compressive stress at all times so that a noise development such as in the form of a rattling noise is avoided during use.

According to one advantageous embodiment of the present invention, the connection section of the frame element has a multitude of slots. These slots are provided especially at regular intervals and may advantageously produce a segmentation, which is able to compensate for transverse displacements in the bonded state. In particular, the frame element may thus be segmented at its bonding surface in order to compensate for mechanical tension caused by temperature-related expansions. This segmentation is able to compensate for stresses in the longitudinal extension.

Additional advantages and embodiments of the present invention result from the description and the figures.

The present invention is schematically illustrated in the figures based on exemplary embodiments and will be described in the following text with reference to the figures.

### BRIEF DESCRIPTION OF THE DRAWINGS

FIG. 1 schematically shows a preferred example embodiment of a display device according to the present invention in a perspective view.

FIG. 2 shows a cutaway of a preferred example embodiment of a display device according to the present invention in a schematic sectional view.

FIG. 3 shows a cutaway of a frame element of a preferred example embodiment of a display device according to the present invention in a schematic sectional view.

### DETAILED DESCRIPTION OF EXAMPLE EMBODIMENTS

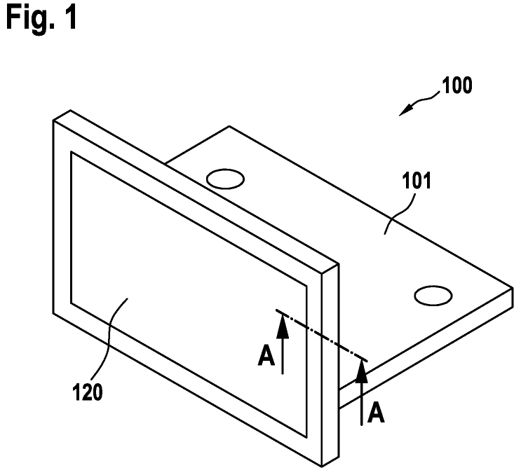

FIG. 1 broadly outlines a preferred embodiment of a display device 100 according to the present invention in a schematic and perspective view.

Display device 100 includes a display element 120 having an electronic display element, e.g., a TFT or LCD display. With the aid of a mounting element 101, for example, display device 100 is able to be mounted in a vehicle, e.g., in an instrument panel region of the vehicle.

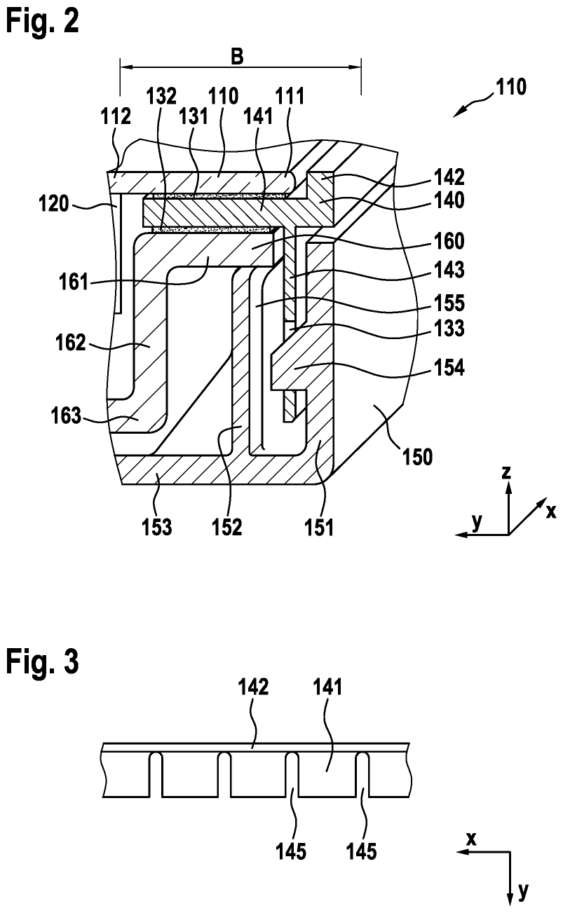

Individual components of display device 100 are specifically developed and connected to one another in certain ways, as described in the following text with reference to FIG. 2.

FIG. 2 schematically shows a cutaway of the display device in a sectional view along the lines A-A shown in FIG. 1.

Display device 100 has a cover element 110, which covers or extends across the entire surface of display element 120. The cover element is produced from a transparent material, e.g., from silicates or an amorphous plastic, e.g., polycarbonate (PC) or polymethyl methacrylate (PMMA).

A cover section 112 of cover element 110 covers display element 120. In this cover section 112, cover element 110 is connected to display element 120 by an adhesive layer (optical bonding). This cover section 112 is adjoined by a connection section 111 which projects beyond display element 120.

A body of display element 120 is at least partly situated inside a carrier element 160, which particularly is provided as a supporting element of display device 100 and, for instance, is made of a light metal such as aluminum or magnesium or their alloys, or from a plastic material, e.g., a plastic material provided with a glass or carbon fiber fill.

Carrier element 160 has a carrier bottom 163 and four side walls 162 which adjoin this carrier bottom at a right angle in each case. The body of display element 120 is at least partly situated inside a volume that is restricted by carrier bottom 163 and side walls 162. A connection section 161 adjoins side walls 161 at an upper end of side walls 162 facing away from carrier bottom 163. This connection section 161 extends at a right angle with respect to side walls 162 in each case.

A frame element 140 is provided which at least partly encloses or frames cover element 110. Frame element 140 in particular has a framing section 142, which circumferentially frames cover element 110. Frame element 140, especially its framing section 142, serves as a decoration of the display device, for example, and forms an accentuated frame and a protection of the edge of the cover element.

For example, frame element 140 is able to be produced from a plastic material which may be dyed or lacquered or galvanically metalized by a post-production process.

In addition, frame element 140 has a connection section 141 adjoining framing section 142 at a right angle and a housing section 143. This housing section 143 extends under a right angle on a side of connection section 141 facing away from framing section 142.

Via connection section 141, frame element 140 is connected both to connection section 111 of cover element 110 and to connection section 161 of carrier element 160.

To this end, a first, upper side of connection section 141 of frame element 140 is connected to connection section 111 of cover element 110 via a first bonded joint 131, in particular via an adhesive tape, in particular a double-sided adhesive tape.

A second, lower side of connection section 141 of frame element 140 facing away from the first side is connected to connection section 161 of carrier element 160 via a second bonded joint 132, in particular via a liquid adhesive.

Double-sided adhesive tape 131 in particular is a tape which has a porous foam in its core. A thin adhesive layer is applied to both sides of this foam core. The porous core is provided to compensate for unevenness of the bonding partners and also to compensate for lateral forces that are created in a thermal expansion of different materials. Adhesive tape 131 furthermore is characterized by its ability to adhere well to glass and plastic and also to metal. The thickness of adhesive tape 131, for example, amounts to between 0.3 to 0.5 mm and particularly is a function of the length of the bonding surface, in particular in relation to a circumferential direction of cover element 110 or in relation to a main extension direction of the bonding surface, in particular in the x-direction in the illustrated example of FIG. 2. Liquid adhesive 132 in particular is meant to compensate for unevenness between carrier element 160 and frame element 140.

Connection section 111 of cover element 110, connection section 141 of frame element 140 and connection section 161 of carrier element 160 are situated one behind the other in an assembly direction z. This assembly direction z runs perpendicular to the main extension plane or surface of cover element 110 defined by coordinate axes x and y.

Frame element 140 and carrier element 160 thus share the space for the connection or fastening, in particular by not being placed next to but underneath one another or one behind the other when viewed in assembly direction z.

In addition, display device 100 has a housing element 150, which particularly is provided as a rear and side cover of display device 100 or as a rear and side housing. This housing element 150 is able to be produced from a plastic material which can be lacquered, for instance. The plastic used may particularly be polypropylene (PP), acrylonitrile butadiene styrene copolymer (ABS) and/or polycarbonate (PC).

Carrier element 160 is at least partly situated in this housing element 150. Housing element 150 has a housing bottom 153 and four double walls which are made up of two individual walls 151, 152 in each case and adjoin the housing bottom. These individual walls 151, 152 are spaced apart from each other by an intermediate region in the y-direction. In addition, the individual walls 151, 152 are arranged parallel to each other and at a right angle with respect to housing bottom 153 in each case.

Housing bottom 153 of housing element 150 especially extends parallel to carrier bottom 163 of the carrier element. In addition, the individual walls 151, 152 of housing element 150 and side walls 162 of carrier element 160 are situated parallel to one another. Carrier element 160 is at least partly situated inside a volume that is restricted by housing bottom 153 and the double walls.

In addition, housing element 150 is connected to frame element 140 via a mechanical connection 133, in particular a plug-in or snap-in connection. For this purpose, the intermediate region between the respective individual walls 151, 152 is provided for the accommodation of housing section 143 of the frame element.

In addition, a multitude of snap-in elements 154 is provided in the intermediate regions between individual walls 151, 152, which cooperate with housing section 143 of frame element 140 for the mechanical connection 133 between frame element 140 and housing element 150.

Housing section 143 of frame element 140 may particularly be developed in the form of a multitude of plug-in elements, which are able to snap into a respective snap-in element 154 so as to produce a plug-in or snap-in connection.

Moreover, spring elements 155 are provided in the intermediate regions between individual walls 151, 152 of the double walls, which exert pressure on housing section 143 of frame element 140.

These spring elements 155 in particular have the function of keeping housing element 150 under tension during and after the connection to frame element 140, so that housing element 150 does not produce any noise such as a rattling noise during use after the assembly. Moreover, following the assembly, spring elements 155 in particular ensure that mechanical connection 133 between housing element 150 and frame element 140 remains securely closed. To stabilize spring elements 155, ribbing with the housing element, for instance, may be provided, which is able to brace spring elements 155 and retain their straight position in the unit in a reliable manner. In addition, carrier element 160, especially connection section 161 of carrier element 160, can be used as counter bearing for spring elements 155, which may function as support.

The more specialized development of the individual elements and the different connection techniques for connecting the individual elements make it possible to give display device 100 a narrow, slim design, in particular with regard to a distance B from an end of display element 120 to an end of frame element 140 or an edge of the display device. The connection techniques that are used in particular make it possible to produce a very narrow rim of the display device (what is termed a slim rim design). Moreover, the cost of the display device can be kept low, e.g., material and production costs. High flexibility is able to be achieved in a design or product design of display device 100, for instance in order to give product designers a large range of shapes and materials. In particular, the used connection techniques allow for the stress-free joining and retaining of the interconnected elements and make it possible to increase what is termed ‘black uniformity’, that is, the ability of display device 100 to display the most uniform, homogeneous black tone.

A liquid adhesive can often be limited in its ability to compensate for lateral expansions. In such cases, for example, connection section 141 of frame element 140 is able to be segmented, as schematically illustrated in FIG. 3, in order to compensate for stresses that occur during a thermal expansion.

FIG. 3 shows a cutaway of frame element 140 in a schematic top view. Connection section 141 of frame element 140 is provided with slots 145 which are disposed at predefined intervals from one another and are meant to compensate for transverse shifting in the bonded state.

1-17. (canceled)

18. A display device for a vehicle, for placement in an instrument panel region of the vehicle, the display device comprising:
a cover element;
a display element having an electronic display element;
a frame element; and
a carrier element, the cover element being situated at a surface of the display element, the frame element at least partly surrounding the cover element circumferentially, the frame element being connected to the cover element via a first bonded joint, and the frame element being connected to the carrier element via a second bonded joint.

19. The display device as recited in claim 18, wherein the frame element is connected to the cover element via a double-sided adhesive tape, as the first bonded joint.

20. The display device as recited in claim 18, wherein the frame element is connected to the carrier element via a liquid adhesive as the second bonded joint.

21. The display device as recited in claim 18, wherein the frame element has a connection section, the frame element is connected via the connection section to a connection section of the cover element and to a connection section of the carrier element.

22. The display device as recited in claim 21, wherein a first side of the connection section of the frame element is connected to the connection section of the cover element, and a second side of the connection section of the frame element facing away from the first side is connected to the connection section of the carrier element.

23. The display device as recited in claim 21, wherein the connection section of the cover element, the connection section of the frame element, and the connection section of the carrier element are situated behind one another when viewed in an assembly direction.

24. The display device as recited in claim 21, wherein the frame element includes a framing section configured to frame the cover element, the framing section adjoining the connection section of the frame element under a predefined angle at an end of the connection section of the frame element.

25. The display device as recited in claim 21, wherein the cover element has a cover section, the cover section covering the display element, and the connection section of the cover element adjoins the cover section and projects beyond the display element.

26. The display device as recited in claim 21, wherein the carrier element has a carrier bottom and side walls which adjoin the carrier bottom, the connection section of the carrier element adjoins the side walls, and the connection section of the carrier element extends under a predefined angle to the side walls perpendicular to the side walls.

27. The display device as recited in claim 26, wherein a body of the display element is situated at least partly inside a volume which is restricted by the carrier bottom and the side walls of the carrier element.

28. The display device as recited in claim 21, wherein the connection section of the frame element is provided with a multitude of slots.

29. The display device as recited in claim 18, wherein the carrier element is at least partly situated in a housing element, and the frame element is connected via a mechanical connection to the housing element.

30. The display device as recited in claim 29, wherein the frame element is connected to the housing element via a mechanical plug-in connection, the plug-in connection being a snap-in connection, as the mechanical connection.

31. The display device as recited in claim 29, wherein the frame element has a connection section, the frame element is connected via the connection section to a connection section of the cover element and to a connection section of the carrier element, and wherein the frame element has a housing section for connection to the housing element, the housing section extending under a predefined angle on a side of the connection section of the frame element facing away from a framing section.

32. The display device as recited in claim 31, wherein the housing element has a housing bottom and double walls adjoining the housing bottom, the carrier element is at least partly situated inside a volume which is restricted by the housing bottom and the double walls, and an intermediate region of the double walls is provided to accommodate the housing section of the frame element.

33. The display device as recited in claim 32, wherein at least one snap-in element is provided in the intermediate region of the double walls of the housing element in each case, which cooperates with the housing section of the frame element for a mechanical connection between the frame element and the housing element.

34. The display device as recited in claim 32, wherein at least one spring element is provided in the intermediate region of the double walls of the housing element, which exerts pressure on the housing section of the frame element.
